(19) United States
(12) Patent Application Publication
(10) Pub. No.: US 2006/0039572 A1
(43) Pub. Date: Feb. 23, 2006

(54) Apparatus and method to limit current of an audio amplifier

(76) Inventor: Byoung-min Mun, Suwon-si (KR)

Correspondence Address: STANZIONE & KIM, LLP, 919 18TH STREET, N.W., SUITE 440, WASHINGTON, DC, 20006, US

(21) Appl. No.: 11/124,091

(22) Filed: May 9, 2005

(30) Foreign Application Priority Data
Aug. 17, 2004 (KR) 2004-64591

(51) Int. Cl. H03G 7/00; H03F 3/38

(52) U.S. Cl. 381/106; 330/10

(57) ABSTRACT

An apparatus and a method to limit a current by having different limiting references according to pulse widths of a current signal in an audio amplifier. The apparatus includes a pulse width modulator to generate a PWM signal by comparing an input audio signal and a reference signal, a power switching unit to switch a voltage source according to the PWM signal generated by the pulse width modulator, a current detector to detect a current signal flowing through a load by the voltage source supplied by the power switching unit, and a controller to apply different limiting values to different current levels according to pulse widths of the current signal detected by the current detector and to control the PWM signal generated by the pulse width modulator by comparing the applied limiting value to a current level value of the current signal detected by the current detector.

### CROSS-REFERENCE TO RELATED APPLICATIONS

This application claims the priority under 35 U.S.C §119 of Korean Patent Application No. 2004-64591, filed on Aug. 17, 2004, in the Korean Intellectual Property Office, the disclosure of which is incorporated herein in its entirety by reference.

### BACKGROUND OF THE INVENTION

1. Field of the Invention

The present general inventive concept relates to a current limiting circuit used in an audio amplifier, and more particularly, to an apparatus and a method of limiting a current by having different limiting references according to pulse widths of a current signal in an audio amplifier.

2. Description of the Related Art

An audio device generally includes an amplifying circuit for amplifying a small signal into a large signal. An electrical audio signal amplified by the amplifying circuit is reproduced into a sound through a speaker or an earphone. The audio device reproduces an original sound through the speaker by controlling an output power of the amplifying circuit. Since a large signal is output in a short time in the audio device, it is necessary to supply a large power. The audio device performs a current limiting operation when the power exceeds a predetermined standard value.

A conventional current limiting circuit is disclosed in Korean Patent Publication No. 2001-8551 (Feb. 5, 2001).

FIG. 1 is a circuit diagram of a conventional current limiting apparatus.

Referring to FIG. 1, the conventional current limiting apparatus includes a current detecting resistor Rs, which is connected to an output terminal Vout⁻ of an adapter through which a source voltage of a power supply is output, a first operational amplifier U1, which compares a reference value “Vref1” and an output current of the output terminal Vout⁻ input through its (+) input terminal and (−) input terminal via respective resistors R1 and R2, a photo coupler PC1, a cathode of a light emitting diode (LED), which is an inside component of the photo coupler PC1, and is connected to an output terminal of the first operational amplifier U1 through a series diode D1 and a series resistor R4, and an anode of the LED, which is connected to an output terminal Vout⁺ of the adapter, a second operational amplifier U2, which compares a sensing voltage generated by passing an output current “lo” over the current detecting resistor Rs and a reference value “Vref2” determined by a resistance ratio of two resistors R8 and R7, a resistor R9 and a capacitor C4, which are connected in series between an output terminal of the second operational amplifier U2 and the ground, a third operational amplifier U3, which compares a value of a contact point of the resistor R9 and the capacitor C4 input through its (+) input terminal and a reference value “Vref3” determined by a resistance ratio of two resistors R10 and R11 input through its (−) input terminal, and a diode D2, a cathode of the diode D2, which is connected to an output terminal of the third operational amplifier U3, and an anode of the diode D2, which is connected to the cathode of the LED of the photo coupler PC1.

The conventional current limiting apparatus delays an output current for a predetermined time when it is determined that a value obtained by comparing an output current level and a reference value is an overcurrent. However, in conventional technologies, when switching components are used for pulse width modulation (PWM), the same reference value must be applied to the switching components regardless of pulse widths of switching voltage sources of the switching components, and safety operating areas (SOAs) of the switching components cannot be sufficiently utilized. Also, if a current is limited to a predetermined reference value when a large power is supplied to a switching component in order to output a large signal from an audio device during a short time, an audio signal may be distorted.

### SUMMARY OF THE INVENTION

The present general inventive concept provides an apparatus and a method to limit a current of an audio amplifier with which a current supplied to predetermined circuit components can be utilized efficiently by setting various current limiting values according to pulse widths of a current signal supplied to loads.

Additional aspects and advantages of the present general inventive concept will be set forth in part in the description which follows and, in part, will be obvious from the description, or may be learned by practice of the general inventive concept.

The foregoing and/or other aspects and advantages of the present general inventive concept are achieved by providing an apparatus to limit a current of an audio amplifier, the apparatus including a pulse width modulator to generate a pulse width modulation (PWM) signal by comparing an input audio signal and a reference signal, a power switching unit to switch a voltage source according to the PWM signal generated by the pulse width modulator, a current detector to detect a current signal flowing through a load by the voltage source supplied by the power switching unit, and a controller to apply different limiting values to different current levels according to pulse widths of the current signal detected by the current detector and to control the PWM signal generated by the pulse width modulator by comparing the applied limiting value to a current level value of the current signal detected by the current detector.

The foregoing and/or other aspects and advantages of the present general inventive concept are also achieved by providing a method of limiting a current of an audio amplifier, the method including generating a PWM signal by comparing an input audio signal and a reference signal, measuring a pulse width of a current signal with respect to a voltage source by switching the voltage source according to the PWM signal, setting a separate current level limiting value according to the measured pulse width of the current signal, and controlling the PWM signal by comparing the current level limiting value to an input current level value.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a circuit diagram of a conventional current limiting apparatus;

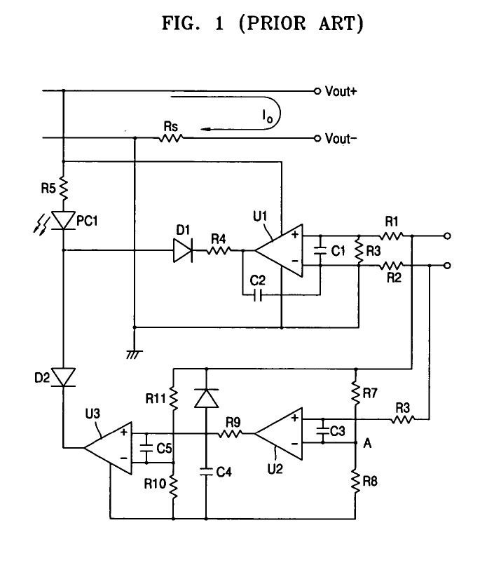

FIG. 2 is a circuit diagram illustrating an apparatus to limit a current of an audio device according to an embodiment of the present general inventive concept;

FIG. 3 illustrates waveforms to operate a PWM unit of the apparatus of FIG. 2;

FIG. 4 illustrates waveforms of a full wave rectifier of the apparatus of FIG. 2;

FIG. 5 is a flowchart illustrating operations of a controller of the apparatus of FIG. 2; and

FIG. 6 is a conceptual diagram illustrating a method of limiting a current in the controller of the apparatus of FIG. 2.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

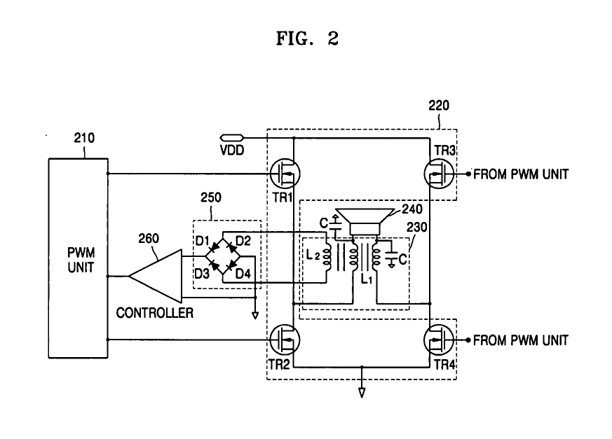

FIG. 2 is a circuit diagram illustrating an apparatus to limit a current of an audio device according to an embodiment of the present general inventive concept.

Referring to FIG. 2, the apparatus includes a pulse width modulation (PWM) unit 210 to generate a PWM signal, a power switching unit 220 to switch a voltage source VDD according to the PWM signal, a speaker 240 to reproduce an audio signal by a switching voltage from the voltage source VDD, a current detector 230 to sense a current signal driving the speaker 240, a full wave rectifier 250 to full-wave-rectify the sensed current signal, and a controller 260 to apply different limiting values to different current levels according to pulse widths of the current signal and to control the PWM signal by comparing the applied limiting values to detected current level values of the current signal.

Operations of the apparatus to limit a current of an audio device will now be described with reference to FIG. 2.

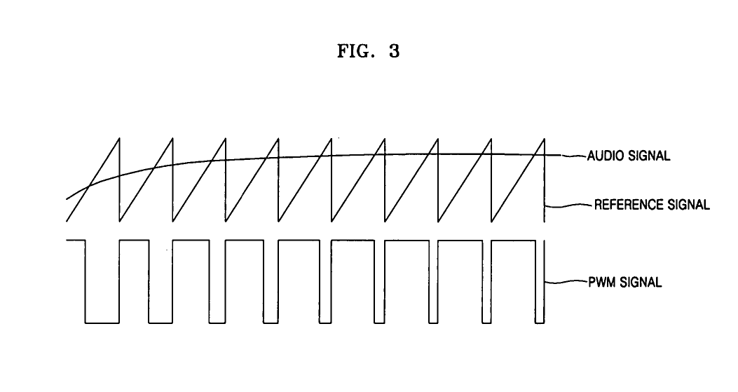

The PWM unit 210 generates a PWM signal by comparing an input audio signal and a reference signal as illustrated in FIG. 3.

The power switching unit 220 switches the voltage source VDD according to the PWM signal generated by the PWM unit 210. That is, the PWM signal generated by the PWM unit 210 is input to gates of switching components, such as a first field effect transistor (FET) TR1, a second FET TR2, a third FET TR3, and a fourth FET TR4, to which the voltage source VDD is supplied. For example, when the first FET TR1 is turned on, the second FET TR2 and the third FET TR3 are turned off, and the fourth FET TR4 is turned on. Also, when the first FET TR1 is turned off, the second FET TR2 and the third FET TR3 are turned on, and the fourth FET TR4 is turned off. A power switched by the power switching unit 220 is supplied to the speaker 240 via a low pass filter (LPF) including a coil L, and a capacitor C. The power switching components have safety operating areas (SOAs) for voltage and/or current in which the components can operate safely. The SOAs, which are characteristic values of the switching components, can be shown as a graph in a parts specification manual. The SOAs for voltage and/or current vary according to a pulse width of a switching power.

The speaker 240 is driven by the switching power filtered by the LPF including the coil L₁ and the capacitor C.

The current detector 230, which includes a current transformer in which a winding wire is added to the coil L₁ of the LPF, converts a current flowing to the speaker 240 into a voltage waveform. That is, if a switching current flows through the coil L₁ of the LPF, a voltage is generated at both ends of a second coil L₂ by a mutual induction effect. When the voltage is generated at both ends of the second coil L₂, the voltage induced to the second coil L₂ is proportional to the switching current. Accordingly, when the switching current flowing through the coil L₁ of the LPF is large, the voltage induced to the second coil L₂ is also large. In another embodiment, the current detector 230 can alternatively sense a current to drive the speaker 240 by using a resistor R.

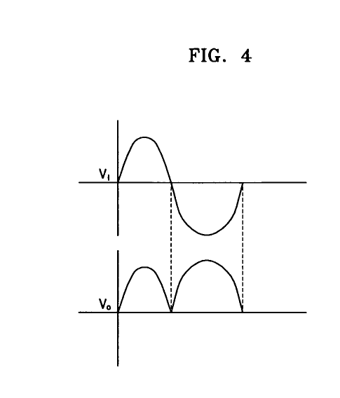

The full wave rectifier 250 transforms the voltage waveform detected by the current detector 230 into a waveform having phases of the same direction using first, second, third, and fourth diodes D1, D2, D3, and D4. For example, as illustrated in FIG. 4, a voltage waveform having positive and negative phases is transformed into a voltage waveform having only positive phases.

The controller 260 measures pulse widths of the voltage waveform output from the full wave rectifier 250, applies different current level limiting values to different current levels according to the measured pulse widths of the voltage waveform, and generates a control signal to control the PWM signal generated by the PWM unit 210 by comparing the applied current level limiting value and the current level value detected by the current detector 230. The current level limiting values according to the pulse widths can be set to optimal values (i.e. the SOAs) based on a user parts specification manual.

The controller 260 appropriately controls an amount of power of the power supply VDD flowing to the speaker 240 by controlling the PWM signal with different limiting references (i.e., the different current level limiting values) according to pulse widths of a current signal.

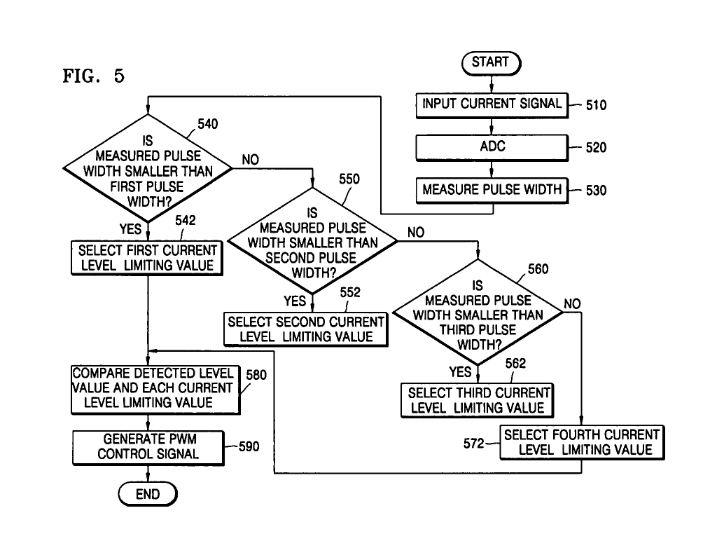

FIG. 5 is a flowchart illustrating operations of the controller 260 of the apparatus of FIG. 2.

Referring to FIG. 5, an analog current signal flowing to the speaker 240 is input at operation 510. The analog current signal is converted into a digital current signal at operation 520.

A pulse width of the converted current signal is measured using a counter at operation 530.

Here, one of different current level limiting values is selected according to the measured pulse width of the current signal. For example, if the measured pulse width of the current signal is determined to be less than a predetermined first pulse width at operation 540, a first current level limiting value is selected at operation 542. If the measured pulse width is determined not to be less than the predetermined first pulse width at operation 540, it is determined whether the measured pulse width is less than a second predetermined pulse width, at operation 550. If the measured pulse width of the current signal is determined to be less than the predetermined second pulse width at operation 550, a second current level limiting value is selected at operation 552. If the measured pulse width is determined not to be less than the predetermined second pulse width at operation 550, it is determined whether the measured pulse width is less than a third predetermined pulse width, at operation 560. If the measured pulse width of the current signal is determined to be less than the predetermined third pulse width at operation 560, a third current level limiting value is selected at operation 562. If the measured pulse width of the current signal is determined not to be less than the predetermined third pulse width at operation 560, a fourth current level limiting value is selected at operation 572.

The selected current level limiting value is compared to a detected current level value at operation 580. A control signal to control the PWM signal is generated according to the comparison result at operation 590.

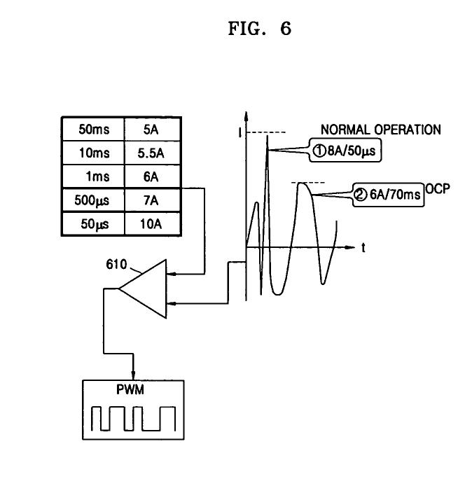

FIG. 6 is a conceptual diagram illustrating a method of limiting a current in the controller 260 of the apparatus of FIG. 2.

Referring to FIG. 6, current limiting values are predetermined according to pulse widths. For example, when the pulse widths are 50 ms, 10 ms, 1 ms, 500 μs, and 50 μs, respectively, their current level limiting values are set to 5A, 5.5A, 6A, 7A, and 10A, respectively. Therefore, a comparator 610 compares a current level limiting value selected according to a pulse width to a detected current level value and outputs a comparison result value as a PWM control signal. For example, it is assumed that a current has various pulse widths according to time t in an audio amplifier, as illustrated in FIG. 6. If a level and a pulse width of the current signal are 8A and 50 μs, respectively, since the level (8A) is not greater than the current level limiting value (10A) of the pulse width (50 μs), the comparator 610 outputs a normal PWM control signal. However, if a level and a pulse width of the current signal are 6A and 70 ms, respectively, since the level (6A) is greater than a set current level limiting value corresponding to the pulse width (70 ms), the comparator 610 outputs a signal to control a PWM signal corresponding to an overcurrent protection (OCP).

As described above, according to the present general inventive concept, by setting various current level limiting values according to pulse widths of a current signal flowing through a load of an audio device, a current flowing through the load can be optimally utilized based on time, and SOAs of current*voltage defined to switch pulse duties with respect to power switching components can be satisfied. Also, an audio signal requiring a large power during a short time can be perfectly reproduced by setting various current level limiting values according to pulse widths of a current signal. Also, an audio circuit having an excellent kicking characteristic can be designed based on a specification of a metal oxide semiconductor field effect transistor (MOSFET) used for a power amplification switch of an audio amplifier and a specification of a part used for an LPF.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An apparatus to limit a current of an audio amplifier, the apparatus comprising:
a pulse width modulator to generate a pulse width modulation (PWM) signal by comparing an input audio signal and a reference signal;
a power switching unit to switch a voltage source according to the PWM signal generated by the pulse width modulator;
a current detector to detect a current signal flowing through a load by the voltage source supplied by the power switching unit; and
a controller to apply different limiting values to different current levels according to pulse widths of the current signal detected by the current detector and to control the PWM signal generated by the pulse width modulator by comparing the applied limiting value to a current level value of the current signal detected by the current detector.

2. The apparatus of claim 1, wherein the controller converts an input analog current signal into a digital signal, measures pulse widths of the converted current signal, sets different current level limiting values according to the measured pulse widths of the current signal, and generates a PWM control signal by comparing the current level limiting value and a detected current level value.

3. The apparatus of claim 2, wherein the current level limiting values according to the pulse widths of the current signal are set based on a user parts specification manual.

4. The apparatus of claim 1, further comprising:
a full wave rectifier to transform phases of the current signal detected by the current detector into the same phase.

5. An apparatus to adjust a current of an audio device, comprising:
a current detector to detect a plurality of current levels of a current through a portion of the audio device; and
a controller to measure a pulse width of each detected current level and to selectively adjust each current level of the current based on a predetermined current level limit corresponding to the respective pulse width.

6. The apparatus of claim 5, further comprising:
a pulse width modulation (PWM) unit to generate a PWM signal based on an input audio signal; and
a power switching unit to generate the current according to the PWM signal generated by the PWM unit, wherein the controller controls the PWM unit to selectively adjust the current levels of the current.

7. The apparatus of claim 6, wherein the power switching unit comprises:
a voltage source to supply a voltage; and
a plurality of switching components to switch the voltage source according to the PWM signal to generate the current.

8. The apparatus of claim 5, wherein the current detector comprises:
a low pass filter to low pass filter the current; and
a coil to detect the plurality of current levels of the filtered current by inducing a voltage proportional to the filtered current.

9. The apparatus of claim 8, further comprising:
a full wave rectifier to transform the voltage induced by the coil of the current detector into a voltage waveform having phases of the same direction, wherein the controller measures the pulse widths based on the voltage waveform.

10. The apparatus of claim 5, wherein the current detector comprises:
a resistor to detect the plurality of current levels of the current.

11. The apparatus of claim 5, wherein the controller comprises:
a comparator to compare each of the detected current levels with the current level limit corresponding to the respective pulse width to determine whether to adjust each of the detected current levels.

12. The apparatus of claim 5, wherein when one of the detected current levels is greater than the current level limit corresponding to the respective pulse width, the controller adjusts the current level.

13. An audio amplifier, comprising:
a pulse width modulation (PWM) unit to generate a PWM signal based on an input audio signal;
a power switching unit to generate a current signal according to the PWM signal;
a speaker to output an audio signal corresponding to the generated current signal;
a current detector to detect a plurality of current levels of the generated current signal; and
a controller to measure a pulse width corresponding to each detected current level, to determine a current level limit based on the measured pulse width, and to control the PWM unit to adjust the current level if the current level is greater than the current level limit based on the respective pulse width.

14. The audio amplifier of claim 13, wherein the controller determines the current level limit based on the measured pulse width by selecting from a plurality of predetermined current level limits, each of the plurality of predetermined current level limits corresponding to a range of pulse widths.

15. A method of limiting a current of an audio amplifier, the method comprising:
generating a PWM signal by comparing an input audio signal and a reference signal;
measuring a pulse width of a current signal with respect to a voltage source by switching the voltage source according to the PWM signal;
setting a separate current level limiting value according to the measured pulse width of the current signal; and
controlling the PWM signal by comparing the current level limiting value to current level value of the current signal.

16. The method of claim 15, wherein the setting a separate current level limiting value according to the measured pulse width of the current signal comprises:
setting the separate current level limiting value according to the measured pulse width of the current signal based on a user parts specification manual.

17. A method of adjusting current levels in an audio amplifier, the method comprising:
determining a plurality of current level limiting values according to a plurality of pulse widths of a current signal; and
selectively adjusting current levels of the current signal according to the plurality of current level limiting values.

18. The method of claim 17, wherein the determining of the plurality of current level limiting values comprises:
selecting the current level limiting values from a plurality of predetermined current level limiting values according to the plurality of pulse widths of the current signal.

19. The method of claim 17, wherein the selectively adjusting the current levels of the current signal comprises:
comparing the current levels of the current signal to corresponding current level limiting values; and
adjusting the current levels of the current signal when the current levels of the current signal are greater than the corresponding current level limiting values.

20. The method of claim 17, wherein the selectively adjusting the current levels of the current signal comprises:
selecting current levels of the current signal to adjust according to the plurality of current limiting values; and
controlling a pulse width modulator to adjust the selected current values of the input current signal.

21. A method of adjusting current levels in an audio amplifier, the method comprising:
detecting a plurality of current levels of a signal;
measuring a pulse width of each detected current level; and
selectively adjusting each current level of the signal according to a predetermined current level limiting value corresponding to the respective measured pulse width.

22. The method of claim 21, wherein the selectively adjusting of each current level of the input signal comprises:
adjusting the current level when the current level is greater than the current level limiting value corresponding to the respective measured pulse width.
